(19) United States
(12) Patent Application Publication
(10) Pub. No.: US 2005/0172891 A1
(43) Pub. Date: Aug. 11, 2005

(54) Dies bonding apparatus and dies bonding method

(76) Inventors: Shinsuke Suzuki, Miyazaki (JP); Shinji Muraki, Tokyo (JP)

Correspondence Address: RABIN & BERDO, P.C., Suite 500, 1101 14th Street, Washington, DC, 20005, US

(21) Appl. No.: 10/892,133

(22) Filed: Jul. 16, 2004

(30) Foreign Application Priority Data
Feb. 5, 2004 (JP) 029857/2004

(51) Int. Cl. B65B 1/00; B65C 1/00; B05C 5/00; H01L 21/44

(52) U.S. Cl. 118/300; 118/313; 438/118; 156/60

(57) ABSTRACT

A dies bonding apparatus is provided with a nozzle unit for supplying an adhesive agent to a rectangular bonding area of a chip mounting surface. The nozzle unit includes a central nozzle for discharging an adhesive agent to the center of the bonding area, and a plurality of peripheral nozzles provided around the central nozzle and whose amount of discharge of the adhesive agent is smaller than the amount of discharge of the adhesive agent from the central nozzle.

### BACKGROUND OF THE INVENTION

1. Field of the Invention

The present invention relates to a dies bonding apparatus and a dies bonding method.

This application is counterparts of Japanese patent application, Serial Number 29857/2004, filed February 5, the subject matter of which is incorporated herein by reference.

2. Description of the Related Art

When a semiconductor chip is bonded to a lead frame or a substrate or semiconductor chips are bonded to each other, the bonding quality of the semiconductor chip exerts an influence on the reliability of a semiconductor. In order to improve the reliability, there is a need to apply a bonding agent to the whole bonding area of the semiconductor chip. The semiconductor chip is hereinafter called simply “chip”.

When a bonding agent is applied onto one point of a central portion and a rectangular chip is bonded to a substrate or the like, the bonding agent is expanded or spread in circular form. Therefore, when the amount of the bonding agent is increased to spread the bonding agent over the whole bonding area of a chip mounting surface, the bonding agent overflows from the bonding area. On the other hand, when the amount of the bonding agent is reduced to avoid overflowing of the bonding agent from the bonding area, the bonding agent cannot be spread over the whole bonding area of the chip.

When the bonding agent overflows from the bonding area in large quantities, the bonding agent reaches a lead portion, thereby causing an electrical short, interfering with a wire connection and causing deterioration of reflow characteristics. Also the bonding quality is deteriorated when the bonding agent is not spread over the whole bonding area of the chip.

In order to spread the bonding agent over the whole chip, there is known a method of applying a bonding agent to a plurality of points of a bonding surface.

A conventional dies bonding apparatus will be explained with reference to FIGS. 6(A) and 6(B). The dies bonding apparatus includes a nozzle unit used to apply a bonding agent and a pressing unit which spreads the bonding agent while a chip is being pressed against a bonding area. FIG. 6(A) is a side view typically showing a schematic configuration of the nozzle unit 110. A plurality of nozzles 130 are mounted to a nozzle mounting portion 120. FIG. 6(B) is a bottom view typically showing a surface on which the nozzles 130 of the nozzle mounting portion 120 are provided. The nozzles 130 have the same circular form and are identical in size, and are arranged in parallel in two rows.

A conventional example showing a dies bonding method using the nozzle unit 110 will be described with reference to FIGS. 7(A) and 7(B). A bonding agent 150 is discharged or delivered from the nozzles 130 provided in the nozzle unit 110 to apply it to a bonding area 146 of a chip mounting surface 44 of a substrate 142. The positions to be coated with the bonding agent 150 are determined according to the positions of the nozzles 130 provided in the nozzle unit 110 (see FIGS. 7(A) and 7(B)).

Next, when a chip 140 is bonded to the chip mounting surface 144 coated with the bonding agent while the chip 140 is being pressed against the chip mounting surface 144, a bonding agent 158 is spread over the chip mounting surface (see FIGS. 7(C) and 7(D)).

In such a case, however, air is confined between the adjacent bonding agents when the bonding agent 158 is spread, thereby producing air bubbles 160, so that portions in which no bonding agent is spread, occur (see FIG. 8). Here, FIG. 8 is a view showing the directions of spreading of bonding agents where the bonding agents equal in quantity are applied to positions corresponding to respective vertexes of a square.

The air bubbles 160 are finally confined in between bonding agents 159 on the chip mounting surface, so that they remain in the bonding area in the form of varying sizes. Therefore, portions in which no bonding agent is applied, occur (see FIGS. 7(E) and 7(F)).

In contrast, an apparatus for uniformly applying a bonding agent to its corresponding bonding area has been proposed (see, for example, a patent document 1). The present document discloses that the bonding agent is applied to the bonding area in the form of a substantially X letter.

Patent Document 1

Japanese Laid Open Patent Application No. Hei 11(1999)-145165.

### SUMMARY OF THE INVENTION

However, the bonding apparatus or bonding method disclosed in the above document encounters difficulties in applying a bonding agent to the whole rectangular bonding area without causing air bubbles under the condition that the bonding agent does not overflow from the rectangular bonding area in large quantities.

The present invention has been made in view of the foregoing problems. Therefore, an object of the present invention is to provide a dies bonding apparatus and a dies bonding method wherein an adhesive agent is widely applied to the whole rectangular area as a bonding agent, no air bubbles remain in between the adhesive agents and the amount of overflowing of the adhesive agent from a bonding area is small.

According to one aspect of the present invention, for achieving the above object, there is provided a dies bonding apparatus, comprising:
a nozzle unit which discharges an adhesive agent to a rectangular bonding area of a chip mounting surface,
the nozzle unit including,
   a central nozzle which discharges the adhesive agent to the center of the bonding area; and
   a plurality of peripheral nozzles provided around the central nozzle and whose amount of discharge of the adhesive agent is smaller than the amount of discharge of the adhesive agent from the central nozzle.

According to the dies bonding apparatus of the present invention, the amount of discharge of the adhesive agent from each of the peripheral nozzles may preferably be smaller than the amount of discharge of the adhesive agent from the central nozzle within the same period of time.

Upon implementation of the present invention, when the bonding area is shaped in the form of a square, preferably, the central nozzle is provided corresponding to a position of a point where diagonal lines of the square intersect, and the peripheral nozzles are respectively provided corresponding to positions on the diagonal lines, excluding the intersecting point of the diagonal lines. Further, the respective peripheral nozzles may preferably be provided at equal intervals in association with the positions on the diagonal lines, excluding the intersecting point of the diagonal lines.

Alternatively, when the bonding area is shaped in the form of a rectangle, preferably, the central nozzle is provided corresponding to a position of a point where diagonal lines of the rectangle intersect, and the peripheral nozzles are respectively provided corresponding to positions on the two sides of isosceles triangles, excluding the bottom sides thereof with the short sides of the rectangle as the bottom sides, and on straight lines connecting both the vertexes of the isosceles triangles and the intersecting point of the diagonal lines. Further, the peripheral nozzles may preferably be respectively provided at equal intervals, corresponding to positions on the two sides of the isosceles triangles except for the bottom sides thereof and on the straight lines connecting the vertexes of the isosceles triangles and the intersecting point of the diagonal lines.

Preferably, the amount of an adhesive agent to be widely applied to the full range of the bonding area may be set as the total amount of the adhesive agents discharged from the central nozzle and the plurality of peripheral nozzles.

Upon implementation of the present invention, the shape of each of discharge ports of the central nozzle and the peripheral nozzles may preferably be circular.

Preferably, the area of the discharge port of the central nozzle may be larger than that of the discharge port of each of the peripheral nozzles.

When the discharge ports of the central nozzle and the peripheral nozzles are circular, preferably, the diameter of the discharge port of the central nozzle is 0.6 mm, the diameter of the discharge port of the peripheral nozzle is 0.5 mm, and the discharge ports of the central nozzle and the peripheral nozzles are laid out at 1.2-mm intervals.

Alternatively, when the discharge ports of the central nozzle and the peripheral nozzles are circular, preferably, the diameter of the discharge port of the central nozzle is 0.6 mm, the diameter of the discharge port of the peripheral nozzle is 0.4 mm, and the discharge ports of the central nozzle and the peripheral nozzles are disposed at 0.8-mm intervals.

Further, preferably, the outermost peripheral nozzles of the plurality of peripheral nozzles may respectively be provided corresponding to areas located within 0.5 mm from the edges of the chip mounting surface.

According to another aspect of the present invention, for achieving the above object, there is provided a dies bonding method, comprising the steps of:
preparing a chip mounting surface having a rectangular bonding area;
supplying an adhesive agent corresponding to a first amount to a central portion of the bonding area;
supplying an adhesive agent corresponding to a second amount smaller than the first amount to a plural points of a peripheral portion, which are located around the central portion; and
pressing a chip against the bonding area supplied with the adhesive agent to thereby widely apply the adhesive agent to the bonding area.

According to the dies bonding method of the present invention, the step for supplying the adhesive agent corresponding to the second amount may preferably be executed simultaneously with the step for supplying the adhesive agent corresponding to the first amount.

Upon implementation of the present invention, when the bonding area is shaped in the form of a square, preferably, the central portion is located at a point where diagonal lines of the square intersect, and the plural points of the peripheral portion are located on the diagonal lines except for the intersecting point of the diagonal lines. Further, the plural points of the peripheral portion may preferably be placed on the diagonal lines excluding the intersecting point at equal intervals.

Alternatively, when the bonding area is shaped in the form of a rectangle, preferably, the central portion is located at a point where diagonal lines of the rectangle intersect, and the plural points of the peripheral portion are positioned on the two sides of isosceles triangles, excluding the bottom sides thereof with the short sides of the rectangle as the bottom sides, and on straight lines connecting both the vertexes of the isosceles triangles and the intersecting point of the diagonal lines of the rectangle. Further, the plural points of the peripheral portion may preferably be positioned on the two sides of the isosceles triangles, excluding the bottom sides thereof with the short sides of the rectangle as the bottom sides and on straight lines connecting both the vertexes of the isosceles triangles and the intersecting point of the diagonal lines of the rectangle.

Preferably, the amount of an adhesive agent to be widely applied to the full range of the bonding area may be set as the total amount of the adhesive agents supplied to the central portion and the plural points of the peripheral portion.

Preferably, the adhesive agents supplied to the central portion and the plural points of the peripheral portion may be supplied such that contours on the surface of the bonding area, of the adhesive agents adhered to the bonding area become circular respectively.

Preferably, the adhesive agent at the central portion is supplied in the form of a circle having a diameter of 0.6 mm, the adhesive agents at the plural points of the peripheral portion are respectively supplied in the form of a circle having a diameter of 0.5 mm, and the adhesive agent at the central portion and the adhesive agents at the plural points of the peripheral portion are respectively supplied at 1.2-mm intervals.

Alternatively, preferably, the adhesive agent at the central portion is supplied in the form of a circle having a diameter of 0.6 mm, the adhesive agents at the plural points of the peripheral portion are respectively supplied in the form of a circle having a diameter of 0.4 mm, and the adhesive agent at the central portion and the adhesive agents at the plural points of the peripheral portion are respectively supplied at 0.8-mm intervals.

Preferably, the outermost points of the plural points of the peripheral portion are located in areas placed within 0.5 mm from the edges of the bonding area.

According to the dies bonding apparatus of the present invention, since the amount of discharge of the adhesive agent from the central nozzle becomes greater than the amount of discharge of the adhesive agent from each of the peripheral nozzles, the amount of the adhesive agent from the central portion to the outside becomes greater than the amount of the adhesive agent from the outside to the central portion. Therefore, the area coated with the adhesive agent is sufficiently ensured at the central portion and the effect of causing air lying between the chip and the chip mounting surface to escape to the outside is enhanced.

Since the peripheral nozzles are respectively provided corresponding to the positions on the diagonal lines except for the intersecting point of the diagonal lines where the bonding area of the chip mounting area is square, the adhesive agents are apt to flow from the center to the outside. Since the peripheral nozzles are provided at equal intervals, the coated adhesive agents becomes more uniform. When the bonding area of the chip mounting area is rectangular, the peripheral nozzles are respectively provided corresponding to the positions on the two sides of the isosceles triangles except for the bottom sides thereof with the short sides of the rectangle as the bottom sides and on the straight lines connecting the vertexes of the isosceles triangles and the intersecting point of the diagonal lines of the rectangle. Therefore, the adhesive agents are apt to flow from the center to the outside. Since the peripheral nozzles are provided at equal intervals, the coated adhesive agents become more uniform.

The amount of the adhesive agent to be widely applied to the full range of the bonding area is set as the total amount of the adhesive agents discharged from the central nozzle and the plurality of peripheral nozzles. Thus, the amount of overflowing of the adhesive agent can be set to a small quantity.

Since the discharge ports of the central nozzle and the peripheral nozzles are made circular, the adhesive agents can be widely applied uniformly from their delivered places.

Since the area of the discharge port of the central nozzle is set larger than that of the discharge port of each of the peripheral nozzles, the amount of discharge of the adhesive agent from the central nozzle can be made greater than the amount of discharge of the adhesive agent from each of the peripheral nozzles.

When the discharge ports of the central nozzle and the peripheral nozzles are circular, the diameter of the discharge port of the central nozzle is 0.6 mm, and the diameter of the discharge port of the peripheral nozzle is 0.5 mm, the centers of the discharge ports of the central nozzle and the peripheral nozzles are placed at 1.2-mm intervals, whereby the adhesive agent is widely applied onto the whole bonding area.

When the discharge ports of the central nozzle and the peripheral nozzles are circular, the diameter of the discharge port of the central nozzle is 0.6 mm, and the diameter of the discharge port of the peripheral nozzle is 0.4 mm, the centers of the discharge ports of the central nozzle and the peripheral nozzles are laid out at 0.8-mm intervals, whereby the adhesive agent is widely applied onto the whole bonding area.

Since the outermost peripheral nozzles of the plurality of peripheral nozzles are respectively provided at the positions where the adhesive agents are delivered to the areas located within 0.5 mm from the edges of the bonding area, the adhesive agent is widely applied to the corners of the bonding area.

According to the dies bonding method of the present invention, the amount of the adhesive agent directed from the central portion to the outside becomes greater than the amount thereof from the outside to the center. Therefore, the area wet by the adhesive agent of the central portion is ensured and the effect of causing air between the chip and the chip mounting surface to escape to the outside is enhanced.

Since there is no need to use a rotation-type nozzle unit and perform stirring for the purpose of uniformly widely applying the adhesive agent to the chip mounting surface, dies bonding can be carried out by a simple method.

When the bonding area is shaped in square form, the adhesive agent corresponding to the first amount is supplied to the position where the diagonal lines of the square intersect, and the adhesive agent corresponding to the second amount smaller than the first amount is supplied to the positions on the diagonal lines except for the intersecting point of the diagonal lines. Therefore, the adhesive agent is apt to flow from the center to the outside. Since the adhesive agent corresponding to the second amount is supplied to the equal-interval positions on the diagonal lines, the adhesive agent is supplied more uniformly.

When the bonding area is shaped in the form of the rectangle, the adhesive agent corresponding to the first amount is supplied to the position where the diagonal lines of the rectangle intersect, and the second amount smaller than the first amount is supplied to the positions on the two sides of the isosceles triangles, excluding the bottom sides thereof with the short sides of the rectangle as the bottom sides, and on the straight lines connecting both the vertexes of the isosceles triangles and the intersecting point of the diagonal lines of the rectangle. Therefore, the adhesive agent is apt to flow from the center to the outside. Further, since the adhesive agent corresponding to the second amount is supplied to the equal-interval positions on the two sides of the isosceles triangles, excluding the bottom sides thereof with the short sides of the rectangle as the bottom sides, and on the straight lines connecting both the vertexes of the isosceles triangles and the intersecting point of the diagonal lines of the rectangle, the adhesive agent is supplied more uniformly.

The amount of the adhesive agent to be widely applied to the full range of the bonding area is set as the total amount of the adhesive agents supplied to the central portion and the plurality of points of the peripheral portion. Consequently, the amount of overflowing of the adhesive agent can be set to a small quantity.

Since the adhesive agents supplied to the central portion and the plural points of the peripheral portion are supplied such that the contours thereof on the surface of the bonding area become circular respectively, the adhesive agents are spread uniformly from their supplied places.

The adhesive agent at the central portion is supplied in the form of the circle having the diameter of 0.6 mm, the adhesive agents at the plural points of the peripheral portion are respectively supplied in the form of the circle having the diameter of 0.5 mm, and the adhesive agents are supplied such that the interval between the adhesive agent at the central portion and each of the adhesive agents at the plural points of the peripheral portion becomes 1.2 mm. Consequently, the adhesive agent is widely applied onto the whole bonding area.

The adhesive agent at the central nozzle portion is supplied in the form of the circle having the diameter of 0.6 mm, the adhesive agents at the plural points of the peripheral portion are respectively supplied in the form of the circle having the diameter of 0.4 mm, and the adhesive agents are supplied such that the interval between the adhesive agent at the central portion and each of the adhesive agents at the plural points of the peripheral portion becomes 0.8 mm. Consequently, the adhesive agent is widely applied onto the whole bonding area.

Since the outermost points of the plural points of the peripheral portion are respectively set to the positions of the areas located within 0.5 mm from the edges of the bonding area, the adhesive agent is widely applied to the corners of the bonding area.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a schematic view for describing the shape of a nozzle unit of a dies bonding apparatus according to a first embodiment of the present invention;

FIG. 2 is a schematic view for describing a dies bonding method according to a first embodiment of the present invention;

FIG. 3 is a view showing the directions of spreading of adhesive agents where the adhesive agents equal in quantity are applied to positions corresponding to respective vertexes of a square and the adhesive agent larger in quantity than those is applied to its central portion;

FIG. 4 is a schematic view for describing the shape of a nozzle unit of a dies bonding apparatus according to a second embodiment of the present invention;

FIG. 5 is a schematic view for describing a dies bonding method according to a second embodiment of the present invention;

FIG. 6 is a schematic view for describing the shape of a nozzle unit of a dies bonding apparatus according to a prior art;

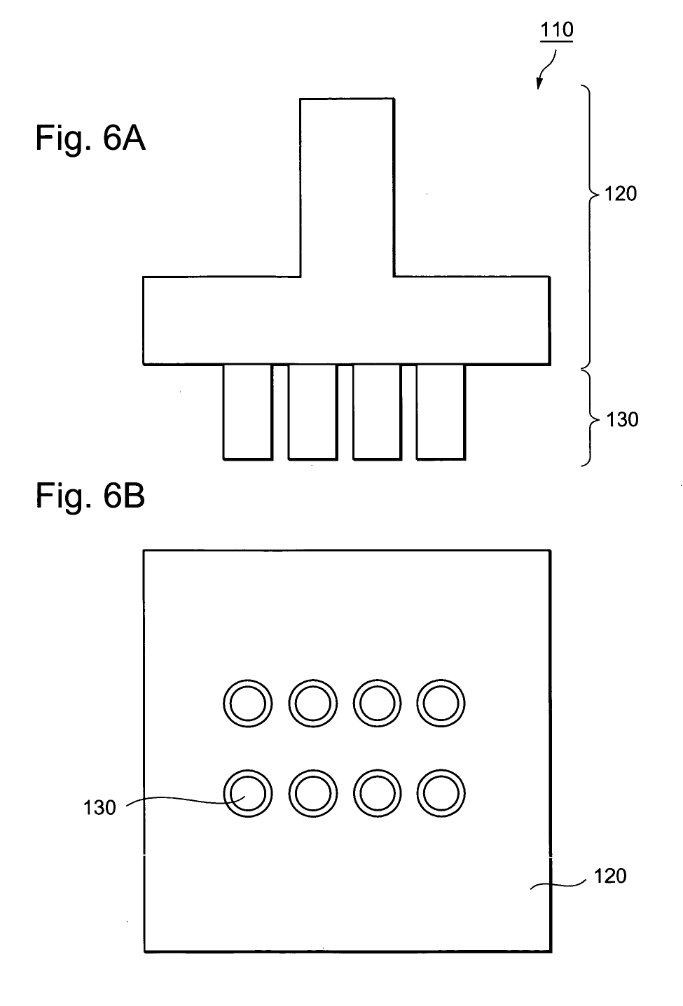

FIG. 7 is a schematic view for describing a dies bonding method according to a prior art; and

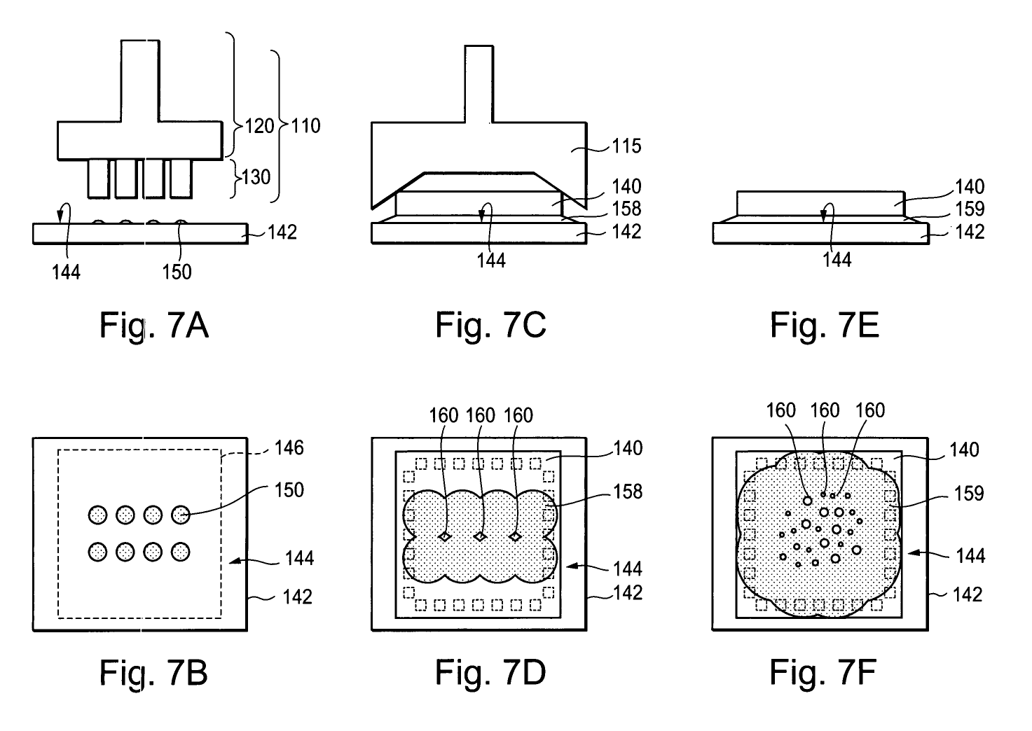

FIG. 8 is a view showing the directions of spreading of bonding agents where the bonding agents equal in quantity are applied to positions corresponding to respective vertexes of a square.

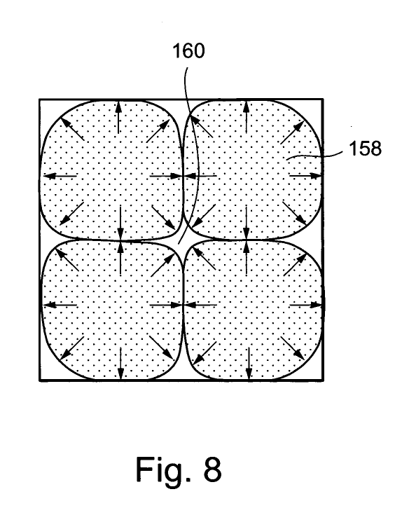

### DETAILED DESCRIPTION OF THE PREFERRED EMBODIMENTS

Embodiments of dies bonding apparatuses and dies bonding methods according to the present invention will hereinafter be described with reference to the accompanying drawings. However, the shape, size and layout relation of respective components are simply schematically shown to such a degree that the present invention can be understood.

Although preferred configurational examples of the present invention are explained below, the composition (material) of respective components and numerical conditions, etc. are simply preferred examples. Therefore, the present invention is not limited to the embodiments described below.

### First Embodiment

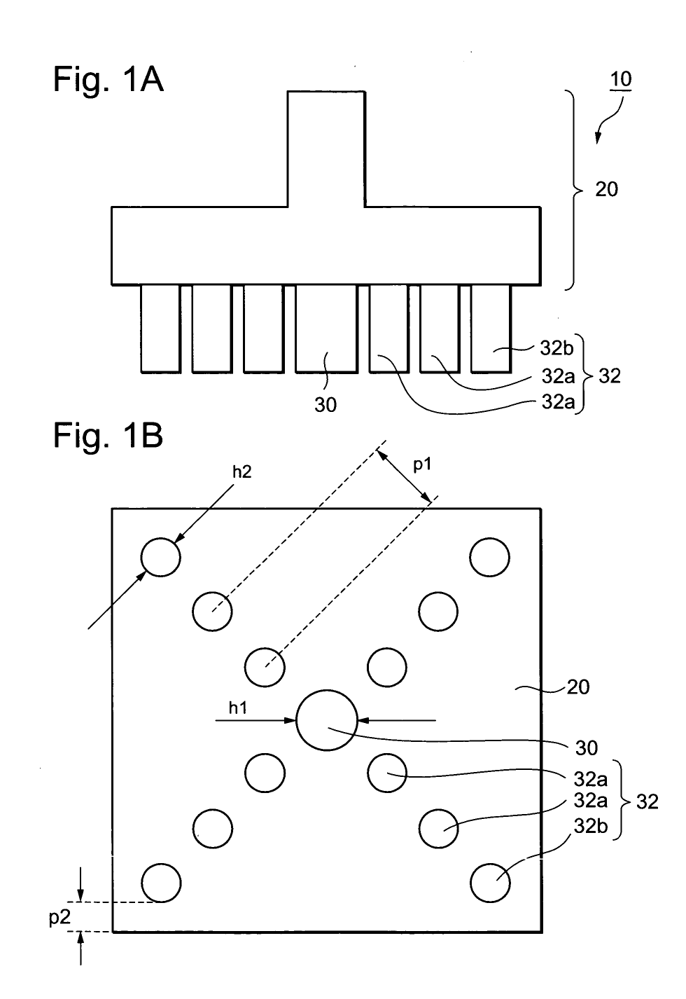

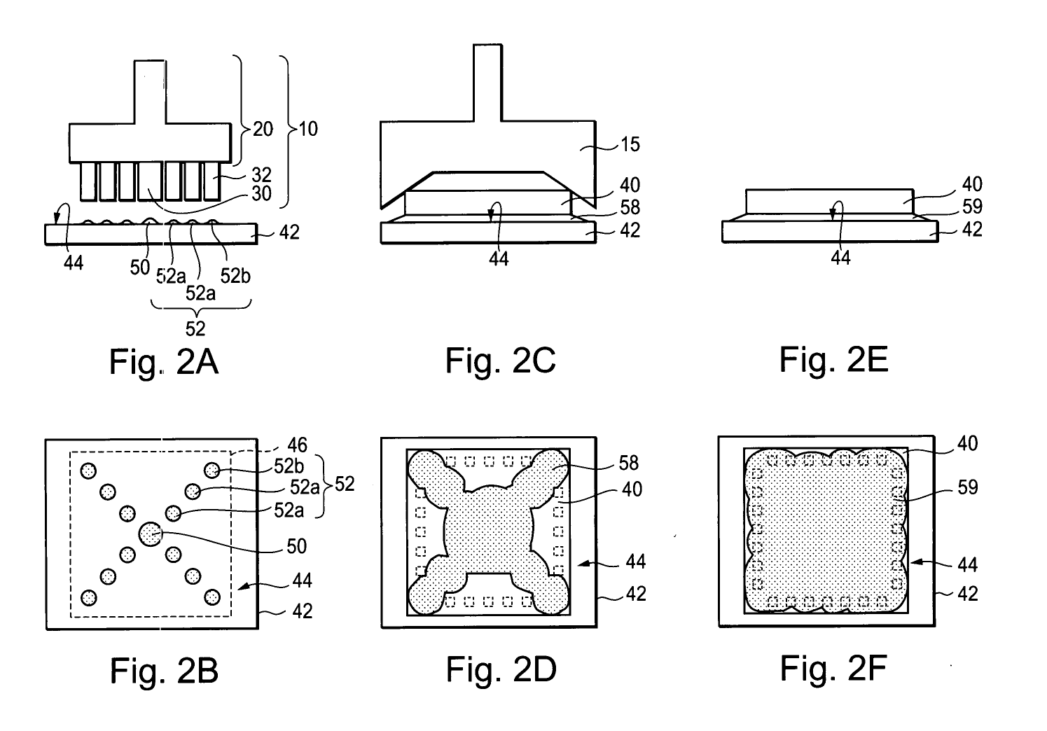

A dies bonding apparatus and a dies bonding method according to a first embodiment will be explained with reference to FIGS. 1(A) and 1(B) and FIGS. 2(A) through 2(F). FIGS. 1(A) and 1(B) are respectively views for describing the shape of a nozzle unit of the dies bonding apparatus. FIG. 1(A) is a schematic side view of the nozzle unit as viewed from its transverse direction with respect to the direction of discharge of adhesive agents. FIG. 1(B) is a schematic bottom view of the nozzle unit as viewed from below, i.e., from a chip mounting surface onto which the adhesive agents are applied. FIGS. 2(A) through 2(F) are views for describing the dies bonding method.

The dies bonding apparatus according to the first embodiment of the present invention includes a non-rotation type nozzle unit 10 and a pressing unit 15. The nozzle unit 10 discharges an adhesive agent to a bonding area of the chip mounting surface. The bonding area may be rectangular and is shaped in the form of a square in the present configurational example. The pressing unit 15 presses a chip against the surface of the bonding area to which the adhesive agent is applied, such that the adhesive agent is spread within the surface of the bonding area uniformly, i.e., it is uniformly applied in an expanded manner. The pressing unit 15 may have the function of holding the chip, laying out the chip on the bonding area of the chip mounting surface and bonding the chip to the chip mounting surface with being pressed against the chip mounting surface. The well-known collet or the like may be used as the pressing unit.

The nozzle unit 10 is provided with a nozzle mounting portion 20, a single central nozzle 30 and a plurality of peripheral nozzles 32a and 32b. The nozzle mounting portion 20 is fitted with the central nozzle 30 and the peripheral nozzles 32 and is capable of being externally supplied with the adhesive agent. However, the nozzle mounting portion 20 may be formed as a structure in which the adhesive agent is stored in the nozzle mounting portion 20 by the required amount thereof, according to settings.

The central nozzle 30 delivers an adhesive agent 50 corresponding to a first amount to the center of the bonding area 46 provided on the chip mounting surface 44, of a substrate 42 for mounting the chip 40 thereon.

The peripheral nozzles 32 are provided around the central nozzle 30. Each of the peripheral nozzles is designed in such a manner that the amount of discharge of the adhesive agent from each of the peripheral nozzles 32 reaches a second amount smaller than the first amount. The adhesive agent is discharged to the bonding area 46 through discharge ports respectively provided for the central nozzle 30 and the peripheral nozzles 32, so that the bonding area 46 is supplied with the adhesive agent. In the present embodiment, the area of the discharge port of the central nozzle 30 is set larger than that of the discharge port of each peripheral nozzle 32, whereby the amount of discharge of the adhesive agent 50 from the central nozzle 30 is set greater than the amount of discharge of the adhesive agent 52 from each peripheral nozzle 32. The peripheral nozzles 32 are made identical to one another in the area of the discharge port. Owing to such a configuration, the amount of discharge of the adhesive agent from each of the peripheral nozzles 32 within the same period of time can be made smaller than the amount of discharge of the adhesive agent from the central nozzle 30. Thus, the process of discharging or delivering the adhesive agent equivalent to the first amount from the central nozzle, and the process of discharging the adhesive agent equivalent to the second amount from each of the peripheral nozzles can be carried out simultaneously. In order to uniformly spread the adhesive agents 50 and 52 from their delivered locations, the shapes of the central nozzle 30 and the peripheral nozzles 30 are respectively made circular.

The amounts of discharge of the adhesive agents from the central nozzle 30 and the peripheral nozzles 32 are reduced and the peripheral nozzles 32 are laid out at narrow intervals, so that the adhesive agents are widely applied more uniformly. Since, however, the size of the discharge port of each of the central nozzle 30 and peripheral nozzles 32 depends on the viscosity of a resin used as the adhesive agent and the amount of its supply, the diameter of the discharge port may preferably be set to greater than or equal to 0.4 mm when the discharge port is shaped in circular form. There is also a need to set the area of the discharge port of the central nozzle 30 greater than that of the discharge port of each peripheral nozzle 32. Since, however, there is a fear that the amounts of discharge of the adhesive agents from the peripheral nozzles 32 will vary when the difference in area therebetween becomes too large, the area of the discharge port of the central nozzle may suitably be set so as to range from, preferably, about 1.2 to 3 times the area of the discharge port of the peripheral nozzle 32. The layout interval between the peripheral nozzles is determined depending on the amounts of discharge of the adhesive agents 50 and 52 from the central nozzle 30 and the peripheral nozzles 32.

In a preferred configurational example, the central nozzle 30 and the peripheral nozzles 32 are laid out such that judging from the above conditions, the diameter h1 of the central nozzle 30 becomes 0.6 mm, the diameter h2 of the peripheral nozzle 32 becomes 0.5 mm, and the distance p1 between the centers of the central nozzle 30 and the peripheral nozzle 32 reaches an interval of 1.2 mm. In another preferred configurational example, the diameter h1 of the central nozzle 30, the diameter h2 of the peripheral nozzle 32 and the distance p1 between the centers of the central nozzle 30 and the peripheral nozzle 32 may also be set as 0.6 mm, 0.4 mm and an interval of 0.8 mm respectively. The nozzle mounting portion 20 may preferably be configured so as to be capable of being separated into, for example, an adhesive agent supply device for supplying the adhesive agent to the central nozzle 30 and the peripheral nozzles 32, and a nozzle mounting plate on which the central nozzle and the peripheral nozzles are laid out. If a plurality of nozzle mounting plates are prepared in advance according to the settings of the chip size, the shapes and sizes of the central nozzle and peripheral nozzles and the layout of the central nozzle and peripheral nozzles, etc., then their implementation becomes easy.

Since the bonding area 46 of the chip mounting surface 44 is shaped in square form in the present embodiment, the central nozzle 30 is provided so as to correspond to the position where the diagonal lines of the bonding area 46 intersect. The peripheral nozzles 32 are respectively provided so as to correspond to positions where they are sequentially spaced away from one another at equal intervals over the diagonal lines of the bonding area 46, except for the intersection of the diagonal lines of the bonding area 46.

In order to widely apply the adhesive agent to the corners of the bonding area 46, the outermost peripheral nozzles 32b of the plurality of peripheral nozzles 32 are preferably provided at positions where the adhesive agent can be supplied to areas in which the distances p2 from the edges of the bonding area 46 of the chip mounting surface 44 fall within 0.5 mm.

The dies bonding method according to the first embodiment will be explained with reference to FIGS. 2(A) through 2(F). Adhesive agents 50, 52a and 52b are applied through the central nozzle 30 and peripheral nozzles 32 provided in the nozzle unit 10. The positions where the adhesive agents 50 and 52 are applied, are placed within the bonding area 46 (indicated by a broken line) provided in the chip mounting surface 44 of the substrate 42. The positions depend on the positions of the central nozzle 30 and the peripheral nozzles 32 mounted to the nozzle mounting potion 20 (see FIGS. 2(A) and 2(B)).

Next, the chip 40 is bonded to the chip mounting surface 44 coated with the adhesive agents 50 and 52 with being pressed against it over the substrate 42. In doing so, the coated adhesive agent 58 is spread within the bonding area 46 of the chip mounting surface 44 (see FIGS. 2(C) and 2(D)).

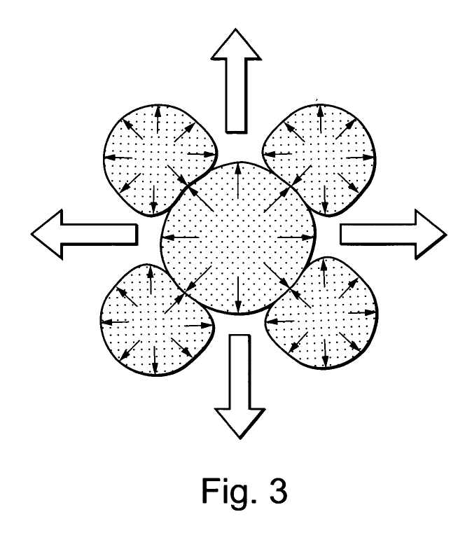

According to the dies bonding apparatus of the first embodiment, the amount of discharge of the adhesive agent 50 from the central nozzle 30 becomes greater than the amounts of discharge of the adhesive agents 52a and 52b from the peripheral nozzles 32, so the amount of the adhesive agent directed from the central portion to the outside becomes greater than the amount thereof from the outside to the center. Since the peripheral nozzles are respectively provided corresponding to the positions on the diagonal lines, which are spaced at equal intervals, with the intersection of the diagonal lines as the center, the adhesive agents are apt to flow from the center to the outside. Therefore, the area coated with the adhesive agent is sufficiently ensured at the central portion and the effect of causing air lying between the chip and the chip mounting surface to escape to the outside is enhanced (see FIG. 3). Now, FIG. 3 is a view showing the directions of spreading of adhesive agents where the adhesive agents equal in quality are applied to positions corresponding to the respective vertexes of a square and the adhesive agent larger in quantity than each of the adhesive agents equal in quality is applied to a central portion.

The total amount of applied adhesive agents V is determined depending on the amount obtained by adding the amount of overflowing of the adhesive agent from the bonding area to the product of a chip area S and the amount of an adhesive agent ρ necessary per unit area. Assuming that the rate (surplus) of the amount of overflowing to the required minimum amount of application Sρ is expressed in r (%), the total amount of applied adhesive agents V is given by the following equation:
V=Sρ(1+r/100)

The amounts of discharge of the adhesive agents from the central nozzle and the peripheral nozzles are determined according to the ratio between the areas of the discharge ports of the respective nozzles. The total amount of applied adhesive agents is set by pressure of a pump used to supply the adhesive agent to the nozzle unit and the time required to supply the adhesive agent.

When the conventional dies bonding apparatus is used, the surplus r is about 50%, whereas the dies bonding apparatus according to the first embodiment is used, the surplus r reaches less than or equal to 10%. When a plurality of adhesive agent application nozzles are arranged in parallel, a loss area of an adhesive agent due to air bubbles of about 25% has occurred. On the other hand, when the dies bonding apparatus according to the first embodiment is used, a loss area of an adhesive agent 59 due to air bubbles reaches less than or equal to 1% (see FIGS. 2(E) and 2(F)).

### Second Embodiment

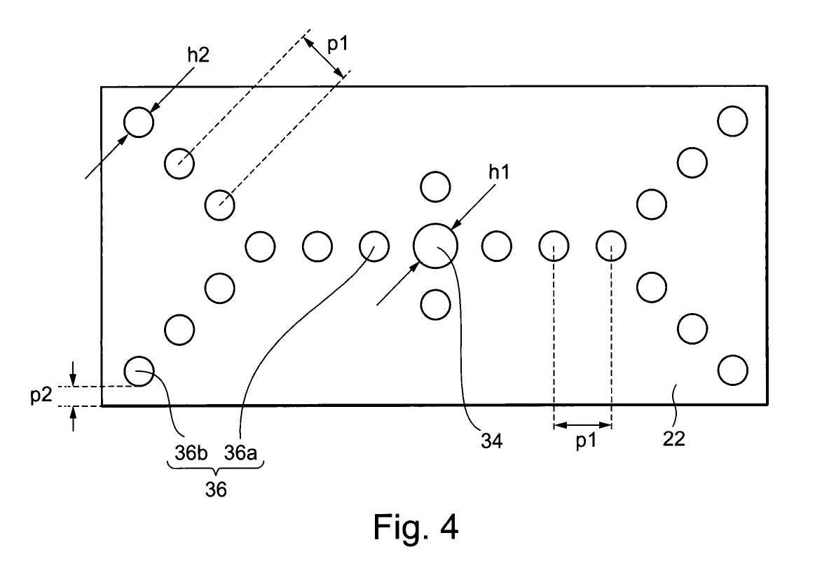

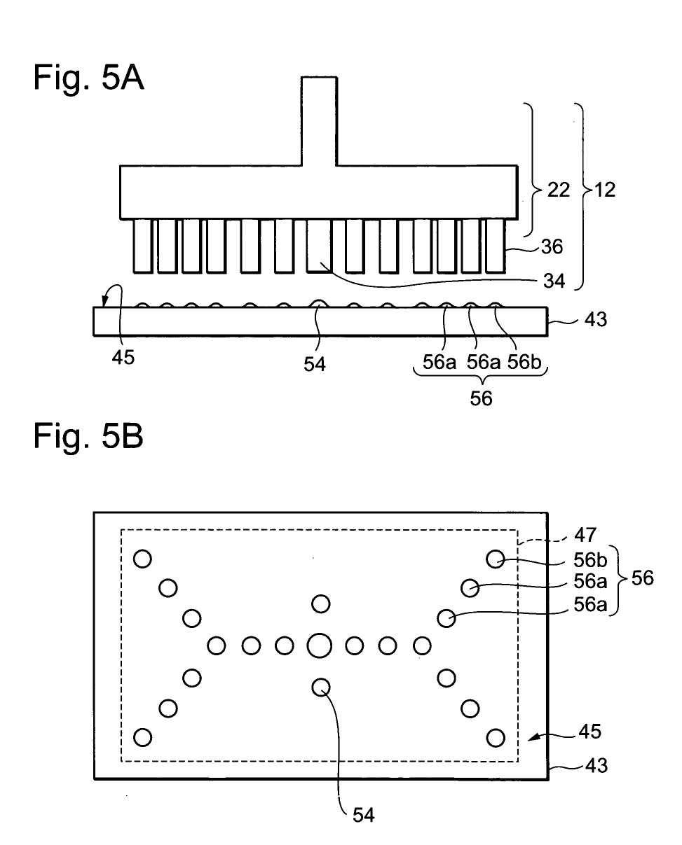

A dies bonding apparatus and a dies bonding method according to a second embodiment will be explained with reference to FIG. 4 and FIGS. 5(A) and 5(B). FIG. 4 is a view for describing the shape of a nozzle unit of the dies bonding apparatus and is a schematic bottom view of the nozzle unit as viewed from below, i.e., from a chip mounting surface on which an adhesive agent is applied. FIGS. 5(A) and 5(B) are respectively views for describing the dies bonding method.

The dies bonding apparatus according to the second embodiment of the present invention includes a non-rotation type nozzle unit 12 which delivers or discharges an adhesive agent to a bonding area of a chip mounting surface, which is rectangular, and a pressing unit (not shown) which uniformly and widely applies the adhesive agent to within the surface of the bonding area while a chip is being pressed against the chip mounting surface to which the adhesive agent is bonded. The pressing unit may have the function of holding the chip, laying out the chip on the bonding area of the chip mounting surface and bonding the chip to the chip mounting surface with being pressed against the chip mounting surface in a manner similar to the first embodiment. The well-known collet or the like may be used as the pressing unit.

The nozzle unit 12 is provided with a nozzle mounting portion 22, a single central nozzle 34 and a plurality of peripheral nozzles 36a and 36b. The nozzle mounting portion 22 is fitted with the central nozzle 34 and the peripheral nozzles 36 and is capable of being externally supplied with the adhesive agent. However, the nozzle mounting portion 22 may be formed as a structure in which the adhesive agent is stored in the nozzle mounting portion 22 by the required amount thereof, according to settings. The shape of a surface on which the central nozzle 34 and the peripheral nozzles 36 are disposed, and the layout of the central nozzle 34 and peripheral nozzles 36 are simply different from those employed in the first embodiment. The outline of the whole configuration is similar to one described in the first embodiment.

The central nozzle 34 supplies an adhesive agent 54 to the center of the bonding area 47 provided on the chip mounting surface 45, of a substrate 43 for mounting the chip thereon.

The peripheral nozzles 36 are provided around the central nozzle 34. Each of the peripheral nozzles is designed in such a manner that the amounts of discharge of adhesive agents from the peripheral nozzles 36 within the same period of time are identical, and the amount of discharge of the adhesive agent from each of the peripheral nozzles 36 within the same period of time becomes smaller than the amount of discharge of the adhesive agent from the central nozzle 34. In the present embodiment, the area of a discharge port of the central nozzle 34 is set larger than that of a discharge port of each peripheral nozzle 36, whereby the amount of discharge of the adhesive agent 54 from the central nozzle 34 is set greater than the amount of discharge of the adhesive agent 56 from each peripheral nozzle 36. The peripheral nozzles 36 are made identical to one another in the area of the discharge port. In order to uniformly spread the adhesive agents 54 and 56 from their delivered locations, the shapes of the discharge ports of the central nozzle 34 and the peripheral nozzles 36 are respectively made circular.

The amounts of discharge of the adhesive agents from the central nozzle 34 and the peripheral nozzles 36 are reduced and the peripheral nozzles 36 are laid out at narrow intervals, so that the adhesive agents are widely applied more uniformly. Since, however, the size of the discharge port of each of the central nozzle 34 and peripheral nozzles 36 depends on the viscosity of a resin used as the adhesive agent and the amount of its supply, the diameter of the discharge port may preferably be set to greater than or equal to 0.4 mm when the discharge port is shaped in circular form. There is also a need to set the area of the discharge port of the central nozzle 34 greater than that of the discharge port of each peripheral nozzle 36. Since, however, there is a fear that the amounts of discharge of the adhesive agents from the peripheral nozzles 36 will vary when the difference in area therebetween becomes too large, the area of the discharge port of the central nozzle may suitably be set so as to range from, preferably, about 1.2 to 3 times the area of the discharge port of the peripheral nozzle 36. The layout interval between the peripheral nozzles is determined depending on the amounts of discharge of the adhesive agents 54 and 56 from the central nozzle 34 and the peripheral nozzles 36.

In a preferred configurational example, the central nozzle 34 and the peripheral nozzles 36 are laid out such that judging from the above conditions, the diameter h1 of the central nozzle 34 becomes 0.6 mm, the diameter h2 of the peripheral nozzle 36 becomes 0.5 mm, and the distance p1 between the centers of the central nozzle 34 and the peripheral nozzle 36 reaches an interval of 1.2 mm. In another preferred configurational example, the diameter h1 of the central nozzle 34, the diameter h2 of the peripheral nozzle 36 and the distance p1 between the centers of the central nozzle 34 and the peripheral nozzle 36 may also be set as 0.6 mm, 0.4 mm and an interval of 0.8 mm respectively. The nozzle mounting portion 22 may preferably be configured so as to be capable of being separated into, for example, an adhesive agent supply device for supplying the adhesive agent to the central nozzle and the peripheral nozzles, and a nozzle mounting plate on which the central nozzle and the peripheral nozzles are laid out. If a plurality of nozzle mounting plates are prepared in advance according to the settings of the chip size, the shapes and sizes of the central nozzle and peripheral nozzles and the layout of the central nozzle and peripheral nozzles, etc., then their implementation becomes easy.

Since the bonding area 47 of the chip mounting surface 45 is shaped in rectangular form in the present embodiment, the central nozzle 34 is provided so as to correspond to the position where the diagonal lines of the bonding area 47 intersect. The peripheral nozzles 36 may preferably respectively be provided so as to correspond to positions where they are spaced away from one another at equal intervals, on the two sides of isosceles triangles, excluding the bottom sides thereof with the short sides of the bonding area 47 as the bottom sides, and straight lines connecting both the vertexes of the isosceles triangles and the intersection of the diagonal lines of the rectangle. Incidentally, FIGS. 4 and 5 show an example in which the isosceles triangles are formed as isosceles right triangles.

In order to widely apply the adhesive agent to the corners of the bonding area 47, the outermost peripheral nozzles 36b of the plurality of peripheral nozzles 36 are provided at positions where the adhesive agent is supplied to areas in which the distances p2 from the edges of the bonding area 47 of the chip mounting surface 45 fall within 0.5 mm.

Since the following process of the dies bonding method is performed in a procedure similar to one described in the first embodiment, its description is omitted. In a manner similar to the first embodiment, the nozzle mounting portion 22 may preferably be separated into an adhesive agent supply device and a nozzle mounting plate on which a central nozzle and peripheral nozzles are disposed. The adhesive agent supply device and the nozzle mounting plate are made detachably engageable so that the nozzle mounting plate is replaced using the same adhesive agent supply device, whereby the first and second embodiments can be realized by the same dies bonding apparatus.

While the present invention has been described with reference to the illustrative embodiments, this description is not intended to be construed in a limiting sense. Various modifications of the illustrative embodiments, as well as other embodiments of the invention, will be apparent to those skilled in the art on reference to this description. It is therefore contemplated that the appended claims will cover any such modifications or embodiments as fall within the true scope of the invention.

1. A dies bonding apparatus, comprising:
a nozzle unit which discharges an adhesive agent to a rectangular bonding area of a chip mounting surface, said nozzle unit including,
a central nozzle which discharges the adhesive agent to the center of the bonding area; and
a plurality of peripheral nozzles provided around the central nozzle and whose amount of discharge of the adhesive agent is smaller than the amount of discharge of the adhesive agent from the central nozzle.

2. A dies bonding apparatus according to claim 1, wherein the amount of discharge of the adhesive agent from each of the peripheral nozzles is smaller than the amount of discharge of the adhesive agent from the central nozzle within the same period of time.

3. A dies bonding apparatus according to claim 1, wherein the bonding area is shaped in the form of a square, the central nozzle is provided corresponding to a position of a point where diagonal lines of the square intersect, and the peripheral nozzles are respectively provided corresponding to positions on the diagonal lines, excluding the intersecting point of the diagonal lines.

4. A dies bonding apparatus according to claim 3, wherein the respective peripheral nozzles are provided at equal intervals in association with the positions on the diagonal lines, excluding the intersecting point of the diagonal lines.

5. A dies bonding apparatus according to claim 1, wherein the bonding area is shaped in the form of a rectangle, the central nozzle is provided corresponding to a position of a point where diagonal lines of the rectangle intersect, and the peripheral nozzles are respectively provided corresponding to positions on the two sides of isosceles triangles, excluding the bottom sides thereof with the short sides of the rectangle as the bottom sides, and on straight lines connecting both the vertexes of the isosceles triangles and the intersecting point of the diagonal lines.

6. A dies bonding apparatus according to claim 5, wherein the peripheral nozzles are respectively provided at equal intervals, corresponding to positions on the two sides of the isosceles triangles except for the bottom sides thereof and on the straight lines connecting the vertexes of the isosceles triangles and the intersecting point of the diagonal lines.

7. A dies bonding apparatus according to claim 1, wherein the amount of an adhesive agent to be widely applied to the full range of the bonding area is set as the total amount of the adhesive agents discharged from the central nozzle and the plurality of peripheral nozzles.

8. A dies bonding apparatus according to claim 1, wherein discharge ports of the central nozzle and the peripheral nozzles are respectively circular.

9. A dies bonding apparatus according to claim 1, wherein the area of the discharge port of the central nozzle is larger than that of the discharge port of each of the peripheral nozzles.

10. A dies bonding apparatus according to claim 8, wherein the diameter of the discharge port of the central nozzle is 0.6 mm, the diameter of the discharge port of the peripheral nozzle is 0.5 mm, and the discharge ports of the central nozzle and the peripheral nozzles are laid out at 1.2-mm intervals.

11. A dies bonding apparatus according to claim 8, wherein the diameter of the discharge port of the central nozzle is 0.6 mm, the diameter of the discharge port of the peripheral nozzle is 0.4 mm, and the discharge ports of the central nozzle and the peripheral nozzles are disposed at 0.8-mm intervals.

12. A dies bonding apparatus according to claim 1, wherein the outermost peripheral nozzles of the plurality of peripheral nozzles are respectively provided corresponding to areas located within 0.5 mm from the edges of the bonding area.

13. A dies bonding method, comprising:
preparing a chip mounting surface having a rectangular bonding area;
supplying an adhesive agent corresponding to a first amount to a central portion of the bonding area;
supplying an adhesive agent corresponding to a second amount smaller than the first amount to a plural points of a peripheral portion, which are located around the central portion; and
pressing a chip against the bonding area supplied with the adhesive agent to thereby widely apply the adhesive agent to the bonding area.

14. A dies bonding method according to claim 13, wherein the step for supplying the adhesive agent corresponding to the second amount is executed simultaneously with the step for supplying the adhesive agent corresponding to the first amount.

15. A dies bonding method according to claim 13, wherein when the bonding area is shaped in the form of a square, the central portion is located at a point where diagonal lines of the square intersect, and the plural points of the peripheral portion are located on the diagonal lines except for the intersecting point.

16. A dies bonding method according to claim 15, wherein the plural points of the peripheral portion are placed on the diagonal lines excluding the intersecting point at equal intervals.

17. A dies bonding method according to claim 13, wherein when the bonding area is shaped in the form of a rectangle, the central portion is located at a point where diagonal lines of the rectangle intersect, and the plural points of the peripheral portion are positioned on the two sides of isosceles triangles, excluding the bottom sides thereof with the short sides of the rectangle as the bottom sides, and on straight lines connecting both the vertexes of the isosceles triangles and the intersecting point of the diagonal lines.

18. A dies bonding method according to claim 17, wherein the plural points of the peripheral portion are positioned on the two sides of the isosceles triangles, excluding the bottom sides thereof and straight lines connecting both the vertexes of the isosceles triangles and the intersecting point of the diagonal lines.

19. A dies bonding method according to claim 13, wherein the amount of an adhesive agent to be widely applied to the full range of the bonding area is set as the total amount of the adhesive agents supplied to the central portion and the plural points of the peripheral portion.

20. A dies bonding method according to claim 13, wherein the adhesive agents supplied to the central portion and the plural points of the peripheral portion are supplied such that contours thereof on the surface of the bonding area become circular respectively.

21. A dies bonding method according to claim 20, wherein the adhesive agent at the central portion is supplied in the form of a circle having a diameter of 0.6 mm, the adhesive agents at the plural points of the peripheral portion are respectively supplied in the form of a circle having a diameter of 0.5 mm, and the adhesive agent at the central portion and the adhesive agents at the plural points of the peripheral portion are respectively supplied at 1.2-mm intervals.

22. A dies bonding method according to claim 20, wherein the adhesive agent at the central portion is supplied in the form of a circle having a diameter of 0.6 mm, the adhesive agents at the plural points of the peripheral portion are respectively supplied in the form of a circle having a diameter of 0.4 mm, and the adhesive agent at the central portion and the adhesive agents at the plural points of the peripheral portion are respectively supplied at 0.8-mm intervals.

23. A dies bonding method according to claim 13, wherein the outermost points of the plural points of the peripheral portion are located in areas placed within 0.5 mm from the edges of the bonding area.
